(19) United States
(12) Patent Application Publication
(10) Pub. No.: US 2005/0148177 A1
(43) Pub. Date: Jul. 7, 2005

(54) Method and an apparatus for manufacturing a semiconductor device

(75) Inventors: Kazuhiro Murakami, Oita-ken (JP); Tomio Katata, Kanagawa-ken (JP); Seiichi Omoto, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/986,406

(22) Filed: Nov. 12, 2004

(30) Foreign Application Priority Data
Nov. 13, 2003 (JP) 2003-383595

(51) Int. Cl. H01L 21/4763; H01L 21/44

(52) U.S. Cl. 438/688; 438/643

(57) ABSTRACT

A method and an apparatus for manufacturing a semiconductor device are provided capable of making a barrier metal layer having a thin film and providing a sufficient barrier property with a low manufacturing cost. The method includes forming a barrier metal layer 5 on predetermined positions on a Cu wiring layer 3 formed on a semiconductor substrate by a CVD method or an ALD method, and forming an Al layer 6 on the barrier metal layer 5 without exposing it to the atmosphere.

### CROSS-REFERENCE TO RELATED APPLICATIONS

This application is based upon and claims the benefit of priority from the prior Japanese Patent Application No. 2003-383595, filed Nov. 13, 2003, the entire contents of which are incorporated herein by reference.

### BACKGROUND OF THE INVENTION

The present invention relates to a method and an apparatus for manufacturing a semiconductor device equipped with a Cu wiring layer.

A wiring pad structure is used for a semiconductor device equipped with a Cu wiring layer. FIG. 1 shows a semiconductor device having such wiring pad structure. An Al layer (Al cap layer) 106 is formed on a Cu wiring layer 103 with a barrier metal layer 105 interposed therebetween. This Al layer is provided to prevent oxidation of the Cu wiring layer 103 and the barrier metal layer 105 is provided to suppress the counter diffusion between the Al layer and the Cu wiring layer 103.

In a barrier metal layer like this, it is necessary that a specified adhesion (for example, bonding strength more than 25 gf) is obtained. For this purpose, a Ti film, a TiN film and a laminated layer film of these films formed according to the PVD (Physical vapor deposition) method are used. Such a barrier metal layer is disclosed in the Published Japanese Patent Application No. 2001-274162.

With the development of the semiconductor devices in its high performance, in its fine circuit structuer, or in its low resistance at the wiring pad portion etc., barrier metal layers having a thinner film is demanded in recent years. However, as a result of the thin filming, in the case of PVD-TiN/Ti films, it is difficult to obtain a sufficient barrier property against Cu and resistance of the pad portion will increase.

When a TaN/Ta film is used, the barrier property is improved. However, a production cost per a lot will increase because Ta target is expensive.

In view of the above, one of the objects of the present invention is to provide a method and an apparatus for manufacturing a semiconductor device which are capable of removing existing defects, suppressing cost increase, providing the barrier metal layer of a thin film having a sufficient barrier property.

### SUMMARY OF THE INVENTION

According to one embodiment of the present invention, there is provided a method for manufacturing a semiconductor device, which comprises forming a barrier metal layer on predetermined positions on a Cu wiring layer formed on a semiconductor substrate by a CVD method or an ALD method, and forming an Al layer on the barrier metal layer in a vacuum or an inert gas without exposing it to the atmosphere.

According to another embodiment of the present invention, there is provided a method for manufacturing a semiconductor device, which comprises forming a groove of a predetermined pattern in a first interlayer insulation film formed on a semiconductor substrate, forming a Cu wiring layer in the groove, forming a second interlayer insulation film on the Cu wiring layer, forming an opening in the second interlayer insulation film reached to the Cu wiring layer, forming a barrier metal layer by a CVD method or an ALD method in a predetermined area including at least the Cu wiring layer on a bottom surface of the opening, and forming an Al layer on the barrier metal layer in a vacuum or an inert gas without exposing the barrier metal layer to the atmosphere.

Also, according to another embodiment of the present invention, there is provided, an apparatus for manufacturing a semiconductor device comprising a first chamber in which a barrier metal layer is formed at a predetermined position on a Cu wiring layer formed on a semiconductor substrate by a CVD method of an ALD method, a second chamber in which the semiconductor substrate with the barrier metal layer formed thereon is conveyed in a vacuum or an inert gas without exposing it to the atmosphere, and a third chamber in which an Al layer is formed on the barrier metal layer formed on the semiconductor substrate, which is conveyed through the second chamber.

### BRIEF DESCRIPTION OF THE DRAWINGS

FIG. 1 is a cross-sectional view showing a wiring pad structure of a semiconductor device manufactured by a conventional method for manufacturing a semiconductor device,

FIG. 2 is a cross-sectional view showing a wiring pad structure of a semiconductor device manufactured by a method for manufacturing a semiconductor device according to a first embodiment of the present invention,

FIG. 3 is a cross-sectional view of the semiconductor device for explaining the method for manufacturing a semiconductor device according to the first embodiment of the present invention,

FIG. 4 is a conceptual diagram of the semiconductor device manufacturing apparatus in the first embodiment of the present invention,

FIG. 5 is a cross-sectional view showing a wiring pad structure of the semiconductor device manufactured by the method for manufacturing semiconductor device according to a third embodiment of the present invention.

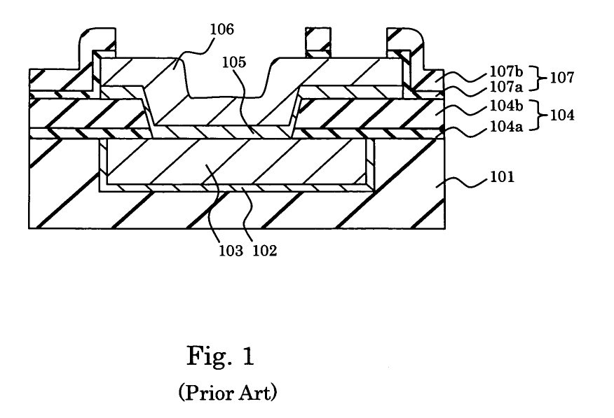

### DETAILED DESCRIPTION OF THE INVENTION

The embodiments of the present invention will be explained hereunder with reference to the accompanying drawings.

### FIRST EMBODIMENT

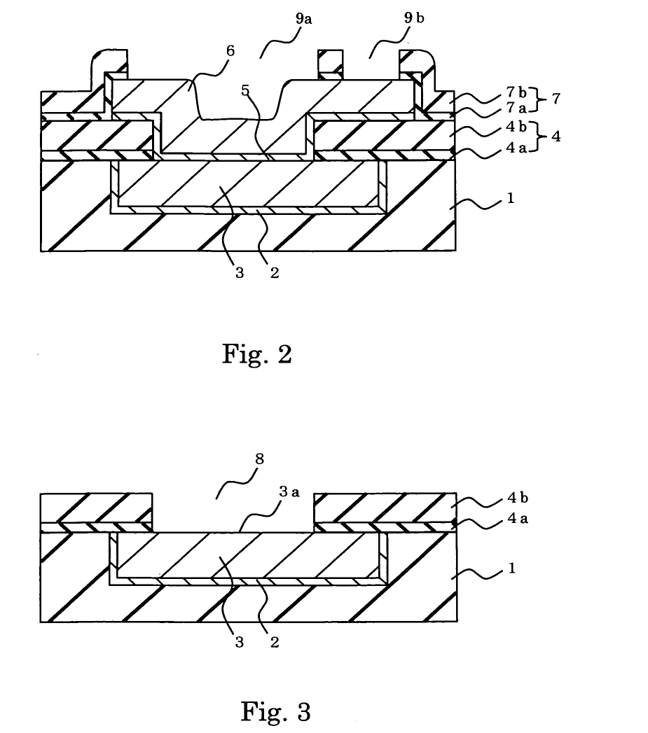

FIG. 2 shows a wiring pad structure of the semiconductor device according to a first embodiment of the present invention. As shown in FIG. 2, an interlayer insulation film 1 is formed on a semiconductor wafer (not shown) with an area (not shown) where active elements and the local wiring, etc. are formed. A Cu wiring layer 3 is formed in a groove formed in the interlayer insulation film 1 with a barrier metal layer 2 made of Ta/TaN, etc. interposed between them.

Then, an interlayer insulation film 4 composed of SiN 4a and P (plazma)-Silane film 4b is formed on an upper surface of the interlayer insulation film 1 including the Cu wiring layer 3. In the interlayer insulation film 4, an opening is so formed to reach the Cu wiring layer 3. A barrier metal layer 5 made of TiSiN film is formed on the interlayer insulation film 4 including a region in the opening, using the CVD method or the ALD method. Further, an Al layer (Al cap) 6 is formed on the barrier metal layer 5. An insulation film 7 made of TEOS film 7a and passivation film 7b is formed at a predetermined position on the Al layer 6, the insulation film 7 being provided with an opening 9a or 9b.

The wiring pad structure in the semiconductor device is formed as described below. As shown in FIG. 3, the interlayer insulation film 1 is formed on the semiconductor wafer (not shown), on which active elements and local wirings, etc. are formed. A groove is formed at a predetermined position of the interlayer insulation film 1. The barrier metal layer 2 made of Ta/TaN films, etc. is formed on an inner surface of the groove. The Cu wiring layer 3 is so formed as to fill the groove.

Then, an opening 8 having a size of 100 μm□, which reaches the Cu wiring layer 3 is formed at a predetermined position of the interlayer insulation film 4. Here, a taper angle, the angle between a bottom surface and a wall surface of the opening 8 is 80° or more.

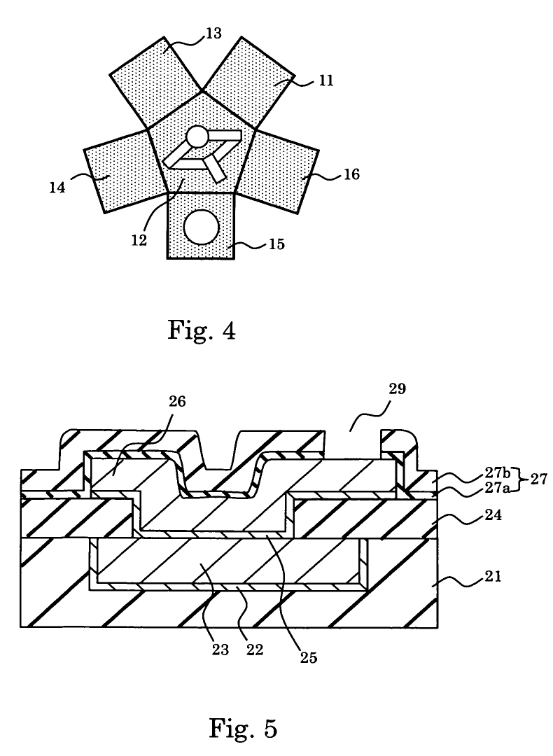

Then, the CVD (ALD) barrier metal layer 5 and the Al layer 6 is formed using an apparatus for manufacturing a semiconductor device, conceptual diagram of which is shown in FIG. 4. As shown in FIG. 4, the semiconductor manufacturing apparatus is made of load lock chambers 11 and 16, a conveying chamber 12, a pre-treatment chamber 13, a CVD (ALD) chamber 14, and a PVD-Al filming chamber 15.

First, a semiconductor wafer with the opening 8 formed shown in FIG. 3 is conveyed from the load lock chamber 11 shown in FIG. 4 to the pre-treatment chamber 13 via the conveying chamber 12.

In the pre-treatment chamber 13, oxides on the Cu wiring layer 3a at the bottom surface of the opening 8 are removed and cleaned by the H2 plasma or Ar plasma treatment. In addition, the similar effect can be obtained by annealing treatment in H2 atmosphere.

Then, the pre-treated semiconductor wafer is conveyed to the CVD (ALD) chamber 14 via the conveying chamber 12.

Then, the TiN film is formed on the whole surface of the semiconductor wafer including the opening 8 by the CVD method or the ALD method. At this time, TDMAT (Ti(N(CH₃)₂)₄)/H₂/N₂ is fed into the CVD (ALD) chamber 14. The semiconductor wafer is subject to a plasma treatment in the H₂/N₂ atmosphere after the TiN film is formed at a wafer temperature 300˜400° C. using TDMAT as source gas.

Then, feeding a Si supply gas such as SiH₄ or Si₂H₆ into the CVD (ALD) chamber 14, the TiN film is exposed to the Si supply gas. As a result, the barrier metal layer 5 made of TiSiN film and having a film thickness of about 20 μm is formed on the Cu wiring layer 3. The semiconductor wafer covered with the TiSiN film is conveyed to the PVD-Al filming chamber 15 via the conveying chamber 12 evacuated to a vacuum or filled with an inert gas without exposing the semiconductor wafer covered with the TiSiN film is to the atmosphere.

Then, Al layer having a thickness of several micron is formed on the whole surface of the TiSiN film in the PVD-Al filming chamber 15. The semiconductor wafer with the Al layer formed is taken out from the load lock chamber 16 and the Al layer is patterned by the usual method. Thereafter, the insulation film 7 made of TEOS film 7a and passivation film 7b is formed on the whole surface of the wafer as shown in FIG. 2. Then, the opening 9a or 9b is formed in the insulation film 7 and the wiring pad structure shown in FIG. 2 is completed.

In the semiconductor devices thus formed, the adhesion between the Cu wiring layer and the Al layer can be improved by forming it on the TiSiN film in the vacume or the inert gas without exposing to the atmosphere. With this TiSiN film, the bonding strength of more than 25 gf can be obtained, which is the same strength as that obtained by the conventional Ti/Ta PVD barrier metal film.

Further, with the film, stable barrer property with less variation can be obtained, because the coverage is better than a PVD barrier metal film. Namely, the thickness of conventional PVD barrier metal film in the opening is thin on the wall surface, and is thick at the center of the bottom surface. While, according to the embodiment of the present invention, the barrier metal film having a uniform thickness in the opening can be obtained irrespective of on the wall surface or on the bottom surface. Further, an enough film thickness can be obtained even if the wall is almost vertical. Conven, it was necessary to provide tapered wall having an angle θ of less than 80° (θ<80°) to obtain a film of enough thickness on the wall surface. Accordingly, the barrier property is improved and producing the thiner film is enabled. Thus, it becomes possible to achieve high integration. Further, it is possible to provide a stable barrier property irrespective of variance in the process conditions (patterns to be processed) resulting from variance in the process conditions for forming the opening.

Further, a process cost can be suppressed without requiring expensive materials including Ta target etc. by using the CVD (ALD) method.

In the embodiment described, a single layer of TiSiN film is formed as a barrier metal layer but it may be formed by plural laminated films. That is, the TiN film may be remained when the TiSiN film is formed by exposing the TiN film to the Si supply gas. Further, forming the TiN and exposing it to the SiH₄ or Si₂H₆ gas may be repeated, for example, twice. Thus, it is possible to provide the barrier metal layers in good quality by forming it in laminated films, which provides a high throughput.

Further, in the embodiment described, a TiN film is formed and plasma-treaed in H₂/N₂ atmosphere. Thus, film density of the barrier metal layer becomes low since it is formed by using the CVD/ALD method using such source gas containning C as TDMAT, etc. However, a higher protective barrier metal layer can be obtained by crystallizing at least a part of the barrier metal layer by subjecting to the plasma-treatment.

Further, in the barrier metal layer that is thus plasma-treated, the film densities somewhat vary. It is possible to further improve the film density and the barrier property by exposing the barrier metal layer to the Si supply gas atmosphere and arranging Si on the film surface. In addition, it becomes possible to further improve the adhesion between Al film and the Cu wiring layer.

In the embodiment described, although TDMAT/H₂N₂ was used as feed gas when forming the TiN film, the feed gas is not restricted to this gas. For example, TDEAT (Ti(N(C₂H₅)₂)₄/NH₃, or TiCl₄/NH₄, etc. may be used.

Further, although SiH₄ or Si₂H₆ was used as a gas to supply Si to at least a part of TiN film, the gas is not especially restricted to them. Any gas capable of supplying Si is usable.

The film thickness of the barrier metal layer is preferable to be less than 60 nm in the above embodiment. When the film thickness is 60 nm or more, resistance of the wiring pad portion cannot be lowered sufficiently.

Further, the lower limit of the film thickness is needed to be a thickness that is able to obtain enough barrier property as the barrier metal layer. From a new knowledge of the inventor, et al., it is found that the barrier property also depends on the area of the opening on the Cu layer (the contacting area with the barrier metal layer) in such a good coverage CVD (ALD) barrier metal layer. That is, the barrier property is obtained even when the film thickness of a barrier metal layer is thin, when the area of the opening is small. However, the barrier property may possibly deteriorate regardless of the area of the opening, when the film thickness is less than 10 nm. Therefore, the thickness of more than 10 nm is necessary.

### SECOND EMBODIMENT

Wiring pad structure of the semiconductor device according to the second embodiment differs from that of the first embodiment in that WN is used for a barrier metal layer. That is, the structure is the same as the structure shown in FIG. 2 but the barrier metal layer 5 is a WN layer.

The wiring pad structure in such semiconductor device is formed as described below. First, likewise the first embodiment, the Cu wiring layer 3 is formed through the barrier metal layer 2 on a semiconductor wafer provided with an element area and local wires, etc. Then, an opening having a size of 100 μm□ is formed on the interlayer insulation film 4.

Then, the barrier metal layer 5 and the Al layer 6 are formed using the apparatus for manufacturing a semiconductor device shown in FIG. 4 in the same way as in the first embodiment. First, the Ar spatter etching process is performed in the pre-treatment chamber 13. As a result of this pre-treatment, oxides on the Cu wiring layer 3a at the bottom surface of the opening are removed and cleaned. Further, the same effect also can be obtained from the annealing process in H₂ atmosphere.

Then, WF₆/NH₃ (Partial Pressure: 0.1˜1 Torr) is fed into the CVD (ALD) chamber 14. And the barrier metal layer 5 made of a WN film having a film thickness of about 20 μm is formed on the whole surface including the opening at the wafer temperature below 300° C. by the CVD method.

Further, a semiconductor wafer with the barrier metal layer 5 formed is conveyed to the PVD-Al filming chamber 15 evacuated to the vacuum or filled with the inert gas without exposing it to the atmosphere as in the first embodiment. Then, the Al film 6 having a film thickness of about 1 μm is formed on the WN film 5. Further, the insulation film 7 is formed and the wiring pad structure as shown in FIG. 2 is completed.

In the semiconductor device thus formed, the same effect in the embodiment 1 can be obtained when the WN film is formed in vacume or inert gas without exposing it to the atmosphere. That is, the adhesion between the Cu wiring layer and the Al layer can be improved. And the bonding strength of more than 25 gf can be obtained as in the case where the conventional Ti or Ta PVD barrier metal film is used. Furthermore, compared with the PVD barrier metal film, better coverage and less variation in specific resistance below 300 μΩ-cm are obtained stably. Also, the barrier property is improved and the thin filming is enabled.

### THIRD EMBODIMENT

The wiring pad structure in the semiconductor device according to the embodiment is shown in FIG. 5. As shown in FIG. 5, the interlayer insulation film 21 is formed on a semiconductor wafer with an area where active elements and local wirings, etc. (not shown) are formed. In a groove formed in the interlayer insulation film 21, the Cu wiring layer 23 is formed with the barrier metal layer 22 made of Ta/TaN, etc. interposed between them. On the interlayer insulation film 21 including the Cu wiring layer 23, the interlayer insulation film 24 made of a low hygroscopic TEOS (Tetra Ethyl Ortho Silicate) film is formed. A barrier metal layer 25 made of TiSiN film is formed in the Cu wiring layer 23 at an area including the opening reaching the Cu wiring layer 23 using the CVD method or the ALD method. Further, the Al layer (Al cap) 26 is formed on barrier metal layer 25. On the predetermined position of the Al layer 26, the insulation film 27 made of a TEOS film 27a and a passivation film 27b provided with the opening 29 is formed.

In the wiring pad structure in the semiconductor device, the Cu wiring layer 23 is first formed on a semiconductor wafer (not shown) with the area (not shown) where active elements and the local wiring, etc. are formed as in the embodiment 1.

Then, a low hygroscopic TEOS is formed on the Cu wiring layer 23 as an interlayer insulation film. Such low hygroscopic TEOS film is formed by applying high frequency electric power of 230 W±5%, at the gass pressure of about 5 Torr and at the substrate temperature of 400±10° C. using the plasma CVD method using TEOS as a source gas. Further, it is necessary to apply higher electric power than the electric power of about 110 W for forming ordinary TEOS film. Thus, a low hygroscopic TEOS film of higher compressive stress than 200 MPa is formed.

At the predetermined position of the thus formed interlayer insulation film (the low hygroscopic TEOS film) 24, an opening having a size of 100 μm□ reaching the Cu wiring layer 23 is formed. Then, the barrier metal layer 25, the Al layer 26 and insulation films 27 made of a TEOS film 27a and a passivation film 27b are sequentially formed as in the first embodiment. At this time, it is preferred to use ordinary TEOS films from the viewpoint of the productivity. Then, the opening 29 is formed in the insulation film 27 and the wiring pad structure as shown in FIG. 5 is completed.

In the wiring pad structure thus formed in the semiconductor device, bonding with external wires is performed at the opening 29. At this time, there was so far such a problem that the adhesion between the interlayer insulation film 24 and the barrier metal layer 25 is reduced due to the bonding stress when an ordinary TEOS film was used for the interlayer insulation film 24. The reason is considered that the problem was caused by moisture contained in the interlayer insulation film. However, a good adhesion can be obtained between the interlayer insulation film 14 and the barrier metal layer 25 by using a low hygroscopic TEOS film for the interlayer insulation film 24. Further, it is possible to improve adhesion between the interlayer insulation film 24 and the barrier metal layer 25 even in an area free from the stress at the time of bonding by the use of such the low hygroscopic TEOS film. Further, the effect of improving adhesion is obtained even when the barrier metal layer is a PVD film.

In the embodiments described above, TiSiN film, TiN/TiSiN film and WN film were used as barrier metal layer, however the embodiments are not restricted to these films. It is possible to use films containing any one of metal film, nitride film, silicide film, silicide-nitride film containing at least one metal element selected from Ti, Zr, Hf, V, Nb, Ta, Cr, Mo, W, and Ni. Further, in this case, a film may be either of a single layer or laminated plural layers.

Further, the present invention is not restricted to the embodiments described above but can be put into practice by changing or modifying variously without departing from the scope of the invention.

According to the embodiments of the method and the apparatus for manufacturing a semiconductor device of the present invention, it is possible to provide the barrier metal layers of a thin film with sufficient barrier property and with a low manufacturing cost.

1. A method for manufacturing a semiconductor device, which comprises:
forming a barrier metal layer on predetermined positions on a Cu wiring layer formed on a semiconductor substrate by a CVD method or an ALD method; and
forming an Al layer on the barrier metal layer in a vacuum or an inert gas without exposing it to the atmosphere.

2. A method for manufacturing a semiconductor device according to claim 1, wherein the forming of the barrier metal layer is performed after cleaning the Cu wiring layer.

3. A method for manufacturing a semiconductor device according to claim 2, wherein plasma-treatment is performed after forming the barrier metal layer.

4. A method for manufacturing a semiconductor device according to claim 1, wherein the barrier metal layer contains any one of a metal film, nitride film, silicide film, silicide-nitride film containing at least one metal element selected from Ti, Zr, Hf, V, Nb, Ta, Cr, Mo, W and Nr.

5. A method for manufacturing a semiconductor device according to claim 4, wherein the barrier metal layer is composed of laminated layers.

6. A method for manufacturing a semiconductor device according to claim 5, wherein the laminated layers is composed of a TiN film and a TiSiN film.

7. A method for manufacturing a semiconductor device according to claim 6, wherein the forming the barrier metal layer further comprising:
forming the TiN film by the CVD method or the ALD method, and
forming the TiSiN film by exposing the TiN film to Si supply gas.

8. A method for manufacturing a semiconductor device according to claim 7, wherein plasma-treatment is performed after forming the TiN film.

9. A method for manufacturing a semiconductor device according to claim 7, wherein at least anyone of TDMA (Ti(N(CH₃)2)4)/H₂N₂, TDEAT (Ti(N(C₂H₅)₂)₄)/NH₃, or TiCl₄/NH₄ is used as source gas of the TiN film.

10. A method for manufacturing a semiconductor device according to claim 9, wherein the Si supply gas include either SiH₄ or Si₂H₆, or both.

11. A method for manufacturing a semiconductor device according to claim 1, wherein the barrier metal layer has a sufficient thickness of less than 60 nm to provide the barrier property.

12. A method for manufacturing a semiconductor device according to claim 11, wherein the film thickness of the barrier metal layer is 10 nm or more.

13. A method for manufacturing a semiconductor device, which comprises:
forming a groove of a predetermined pattern in a first interlayer insulation film formed on a semiconductor substrate;
forming a Cu wiring layer in the groove;
forming a second interlayer insulation film on the Cu wiring layer;
forming an opening in the second interlayer insulation film reaching the Cu wiring layer;
forming a barrier metal layer by a CVD method or an ALD method in a predetermined area including at least the Cu wiring layer on the bottom surface of the opening; and
forming an Al layer on the barrier metal layer in a vacuum or an inert gas without exposing the barrier metal layer to the atmosphere.

14. A method for manufacturing a semiconductor device according to claim 13, wherein forming the barrier metal layer is performed after cleaning the Cu wiring layer on the bottom surface of the opening.

15. A method for manufacturing a semiconductor device according to claim 13, wherein the second interlayer insulation film contains a low hygroscopic TEOS film.

16. A method for manufacturing a semiconductor device according to claim 15, wherein forming the second interlayer insulation film further comprises forming a TEOS film using a plasma CVD method by applying electric power of 230 W±5%.

17. An apparatus for manufacturing a semiconductor device comprising:
a first chamber in which a barrier metal layer is formed at a predetermined position on the Cu wiring layer formed on a semiconductor substrate by a CVD method or an ALD method;
a second chamber in which the semiconductor substrate with the barrier metal layer formed is conveyed in a vacuum or an inert gas without exposing it to the atmosphere; and
a third chamber in which an Al layer is formed on the barrier metal layer of the semiconductor substrate conveyed through the second chamber.

18. An apparatus for manufacturing a semiconductor device according to claim 17, further comprising:
a fourth chamber in which the surface of the Cu wiring layer formed on the semiconductor substrate is cleaned up; and
a fifth chamber in which the cleaned semiconductor substrate is conveyed in the vacume or the inert gas without exposing it to the atmosphere.
